(19) United States
(12) Patent Application Publication
(10) Pub. No.: US 2023/0307250 A1
(43) Pub. Date: Sep. 28, 2023

(54) METHOD FOR PRODUCING AN APPARATUS HAVING A METAL BODY FOR COOLING A SEMICONDUCTOR ARRANGEMENT

(71) Applicant: Siemens Aktiengesellschaft, 80333 München (DE)

(72) Inventors: PHILIPP KNEISSL, Nürnberg (DE); FLORIAN SCHWARZ, Fürth (DE); VOLKER MÜLLER, Nürnberg (DE); STEPHAN NEUGEBAUER, Erlangen (DE); VLADIMIR DANOV, Erlangen (DE)

(73) Assignee: Siemens Aktiengesellschaft, 80333 München (DE)

(21) Appl. No.: 18/125,442

(22) Filed: Mar. 23, 2023

(30) Foreign Application Priority Data
Mar. 24, 2022 (EP) 22164158.2

(51) Int. Cl. H01L 21/48; H01L 23/427

(52) U.S. Cl. CPC H01L 21/4871; H01L 23/427; H01L 24/48; H01L 2224/48247

(57) ABSTRACT

In a method for producing an apparatus for cooling a semiconductor arrangement, a first cooling channel is produced in a metal body with a first FSC (Friction Stir Channeling) at a first depth from a surface of the metal body. Using the first FSC method, a first connecting channel is produced extending from the first cooling channel to the surface of the metal body. Using second FSC method a second cooling channel is produced in the metal body at a second depth from the surface of the metal body, with the second depth being smaller than the first depth. The first connecting channel forms a fluidic connection between the first cooling channel and the second cooling channel, and the first and second cooling channels and the first connecting channel form a cooling channel structure.

### CROSS-REFERENCES TO RELATED APPLICATIONS

This application claims the priority of European Patent Application, Serial No. 22164158.2, filed Mar. 24, 2022, pursuant to 35 U.S.C. 119(a)-(d), the content of which is incorporated herein by reference in its entirety as if fully set forth herein.

### BACKGROUND OF THE INVENTION

The invention relates to a method for producing an apparatus for cooling a semiconductor arrangement, and to an apparatus for cooling a semiconductor arrangement. Furthermore, the invention relates to a semiconductor arrangement and to a converter with a semiconductor arrangement.

The following discussion of related art is provided to assist the reader in understanding the advantages of the invention, and is not to be construed as an admission that this related art is prior art to this invention.

An apparatus of this type find application, for example in a converter. A converter is understood to be a rectifier, an inverter, a transducer or a DC converter, for example. Semiconductor arrangements in a converter are usually realized in the form of power semiconductor modules which are currently mainly pressed by screws against a cooling body. Particularly in the case of greater powers, cooling bodies are used which have cooling channels that contain a heat transfer medium, in particular a cooling fluid.

To date, fluid-cooled cooling bodies with cooling channels are produced using milling, casting and reshaping, wherein the grooves that are produced for the cooling channels are initially open and only closed in a further manufacturing step. (Vacuum) hard soldering, laser welding or screwing together with providing a seal are methods used to close the grooves. Alternatively, separate tubes that are thermally and mechanically connected to the remaining cooling plate are pressed into the channels. Further possibilities for producing cooling bodies of this type are deep-hole drilling or extrusion profiles, wherein it is necessary in a further manufacturing step to close and connect the end sides of the cooling channels respectively.

The increasing miniaturization of electronic power systems in converters presents new demands with respect to cooling a semiconductor arrangement in order to ensure a high degree of reliability while requiring a small amount of space, also taking into consideration the production costs.

It would be desirable and advantageous to provide an improved method for producing an apparatus for cooling a semiconductor arrangement which method obviates prior art shortcomings, is cost-effective and simple, and improves cooling of a semiconductor arrangement.

### SUMMARY OF THE INVENTION

According to one aspect of the present invention, a method for producing an apparatus having a metal body for cooling a semiconductor arrangement includes: producing by means of a first FSC (Friction Stir Channeling) method a first cooling channel at a first depth in the metal body, producing by means of the first FSC method a first connecting channel which is arranged running from the first cooling channel to an, in particular planar, surface of the metal body, producing by means of a second FSC method a second cooling channel at a second depth in the metal body, wherein the second depth is smaller than the first depth, producing a fluidic connection between the first cooling channel and the second cooling channel via the first connecting channel, with the cooling channels and the first connecting channel forming a cooling channel structure.

According to another aspect of the invention, an apparatus for cooling a semiconductor arrangement includes a metal body, and a cooling channel structure including a first cooling channel extending in the metal body at a first depth from a surface of the metal body and produced by using a first FSC method, a second cooling channel extending in the metal body at a second depth from the surface and produced by using a second FSC method, and a first connecting channel extending in the metal body from the first cooling channel to the surface and produced by using the first FSC method, with the first connecting channel connecting the first cooling channel in a fluidic manner to the second cooling channel.

According to yet another aspect of the invention, a semiconductor arrangement includes a semiconductor element and an apparatus of the aforedescribed type, wherein the semiconductor element is connected to the apparatus for thermal conduction.

According to yet another aspect of the invention, a converter includes at least one semiconductor arrangement of the afore-described type.

The invention is based on an idea of improving the cooling of a semiconductor arrangement by using a cooling apparatus having cooling channels arranged on multiple levels. The cooling channels are produced in the apparatus using FSC methods in a cost-effective and simple manner. The cooling apparatus includes a metal body having a surface which is advantageously essentially planar. The metal body can have, i.a., cooling ribs and/or cooling fins on at least one side that is remote from the planar surface. The essentially planar surface of a metal body of this type allows the FSC method to be performed in a simpler and more cost-effective manner. The metal body can be configured, i.a., in a cuboid shape. A first cooling channel is produced by using a first FSC method at a first depth in the metal body. Subsequently, a first connecting channel is produced by using the first FSC method and the first connecting channel extends from the first cooling channel to the surface of the metal body. In a further step, a second cooling channel is produced by using a second FSC method at a second depth in the metal body, wherein the second depth is smaller than the first depth. The first connecting channel produces a fluidic connection between the first cooling channel and the second cooling channel. For example, the second cooling channel is arranged in such a manner that the first connecting channel extends into the second cooling channel. The first and second cooling channels and the first connecting channel form a cooling channel structure. The first FSC method and the second FSC method can differ, i.a., by at least parts of the tool that is used, for example by the rotating probe that is used in each case or by the welding mandrel that is used in each case. Additional cooling channels in further depths, which are connected via further connecting channels, can be produced in a similar manner by using further FSC methods, allowing the production of complex inner connections, a parallel cooling fluid guide, bypasses and individual cooling channel structures in a cost-effective, simple and flexible manner.

Using the FSC methods, it is possible to produce cooling channels that have a rectangular, in particular square cross-section which have a greater surface area in particular in comparison to a round cross-section. Moreover, a channel surface is rougher, in particular in comparison to milled channels, which additionally increases the contact area of a cooling fluid in the case of the metal body and thus improves the cooling efficiency.

According to another advantageous feature of the invention, the first connecting channel can extend essentially perpendicularly to the first cooling channel and/or to the surface of the metal body. An arrangement of this type makes the FSC method simple and cost-effective, in particular in the case of a planar surface of the metal body.

According to another advantageous feature of the invention, the first cooling channel and/or the second cooling channel can be arranged essentially parallel to the surface of the metal body. A parallel arrangement of this type ensures a uniform heat transfer.

According to another advantageous feature of the invention, the first cooling channel can be produced with a tool having a first welding mandrel and the second cooling channel is produced with a tool having a second welding mandrel, wherein the first welding mandrel is longer than the second welding mandrel. The depth of the respective channel can be determined by the length of the employed welding mandrel, with the length being measured for example from the shoulder of the tool. In this case, the channels can be produced with different tools having welding mandrels of different lengths, which facilitates a rapid production. Alternatively, the channels can be produced using the same tool, in which case the welding mandrel is changed for producing the respective channel, which reduces the tool costs. Welding mandrels configured in this manner ensure that the channels produced by the respective FSC method are closed and flush with the surface.

According to another advantageous feature of the invention, a channel height of a cooling channel can be modified by varying a rotational speed of a tool and/or by varying a traverse speed of a tool. The rate at which material is conveyed depends i.a. on the tool geometry, the rotational speed, the traversing speed and the plasticization of the material. If more material is moved out at one site, a channel at this site is taller, with the result that the channel height can be modified in a simple and cost-effect manner by varying the rotational speed and/or by varying the traversing speed. For example, a contour in the region of a channel ceiling may be produced, in particular, by gradually varying process parameters of this type.

According to another advantageous feature of the invention, a channel width of the first connecting channel can be modified by gradually decreasing and/or increasing the rotational speed and/or traversing speed of a tool. For example, a tapering connecting channel may thereby be produced in a simple and cost-effective manner.

According to another advantageous feature of the invention, at least one of the first and second cooling channels can extend in a meandering manner. A meandering cooling channel structure can be produced using the FSC method over a large area in one process step and consequently in a simple and cost-effective manner and enables an efficient cooling and heat dissipation.

According to another advantageous feature of the invention, the method further includes producing by using the second FSC method a supply channel extending from the second cooling channel to a surface of the metal body, filling the cooling channel structure via the supply channel with a heat transfer fluid and closing the supply channel. A heat transfer fluid of this type can be electrically conductive or electrically non-conductive. I.a., air, in particular deionized, water, a water-glycol mixture, dielectric fluids and/or oils are possibilities. For example, a removable sealing plug can close the supply channel, in particular in a fluid-tight manner, after cooling channel structure has been filled. A supply channel is created usually as a by-product during the second FSC method. By using the supply channel for filling the cooling channel structure with a heat transfer fluid, the production process is further simplified and the production costs are further reduced by reducing manufacturing steps.

According to another advantageous feature of the invention, the cooling channel structure can be configured with the heat transfer fluid for a two-phase cooling. Examples for a two-phase cooling include, i.a., a thermo-siphon, a heat pipe or a pulsating heat pipe. Advantageously, due to its high heat conductivity, its boiling point and its dielectric characteristics, perfluoro-N-alkyl-morpholino is very suitable as an electrically non-conductive heat transfer medium for the two-phase cooling. A two-phase cooling of this type enables an efficient cooling.

According to another advantageous feature of the invention, the metal body can be produced from aluminum, copper or one of their alloys. A material of this type can be processed easily with the FSC method. Moreover, it is possible to produce an efficient electrical and thermal connection.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a schematic cross-sectional view of a method for producing a cooling apparatus,

FIG. 2 shows a schematic cross-sectional view of a first embodiment of a semiconductor arrangement,

FIG. 3 shows a schematic cross-sectional view of a second embodiment of a semiconductor arrangement,

FIG. 4 shows a schematic three-dimensional representation of a cooling apparatus, and

FIG. 5 shows a schematic view of a converter.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

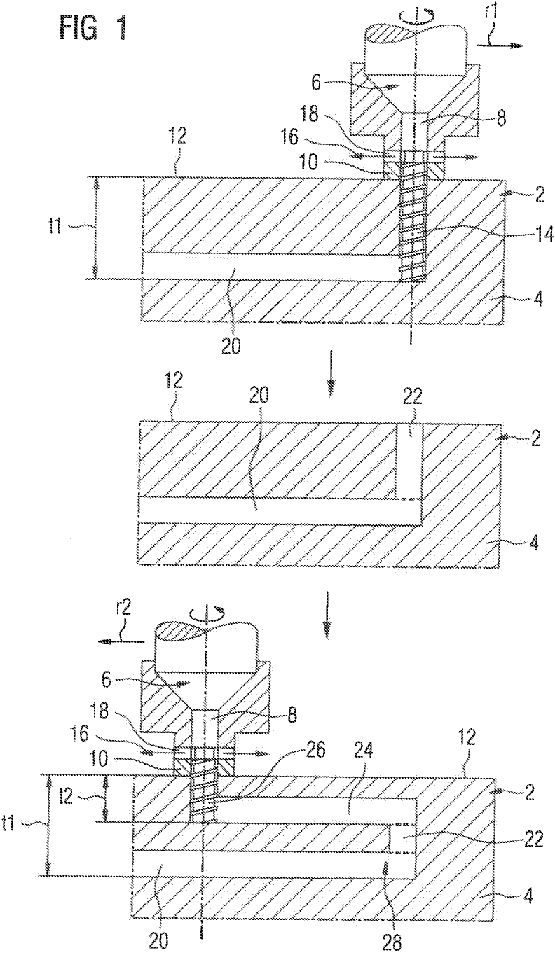

Turning now to the drawing, and in particular to FIG. 1, there is shown a schematic cross-sectional view of a method for producing a cooling apparatus 2 having a metal body 4. The metal body 4 can be made, i.a., of aluminum, copper or one of their alloys. The cooling apparatus 2 is produced by using a FSC method. A FSC (Friction Stir Channeling) method of this type is a development of the friction stir welding method in which the friction stir method is modified so that the material is intentionally moved out of the body of the workpiece and a channel is formed in this manner. A tool 6 having a rotating probe 8 plunges in the metal body 4 and is moved in a first movement direction r1, wherein a shoulder 10 contacts a, in particular planar, surface 12 of the metal body 4. The rotating probe 8 has a thread-type profiled welding mandrel 14. The metal material of the metal body 4 is plasticized by rotationally moving the thread-type profiled welding mandrel 14. A part of the plasticized material is extruded 16 and ejected via at least one extrusion opening 18. Subtracting material in this manner leads to the formation of the closed channel which runs below the surface 12.

In a first step, a first cooling channel 20 is produced by using a first FSC method at a first depth t1 in the metal body, wherein the first cooling channel 20 is produced with a tool 6 having a first welding mandrel 14. The first cooling channel 20 is arranged essentially parallel to the planar surface 12 of the metal body 4.

Subsequently, a first connecting channel 22 is produced by using the first FSC method and extends from the first cooling channel 20 to the planar surface 12 of the metal body 4. The first connecting channel 22 extends essentially perpendicular to the first cooling channel 20 and to the surface 12 of the metal body 4.

In a further step, a second cooling channel 14 is produced by using a second FSC method at a second depth t2 in the metal body, wherein the second depth t2 is smaller than the first depth t1. The second cooling channel 24 is produced with a tool 6 having a second welding mandrel 26 which is shorter than the first welding mandrel 14 and is moved in a second movement direction r2. The second cooling channel 24 also extends essentially parallel to the planar surface 12 of the metal body 4. The first connecting channel 22 produces a fluidic connection between the first cooling channel 20 and the second cooling channel 24, with the cooling channels 20, 24 and the first connecting channel 22 forming a cooling channel structure 28.

By using a FSC method successively in different working depths on the same metal body 4, cooling channels 20, 24 can be produced at different depths t1, t2, thereby producing a complex cooling channel structure 28.

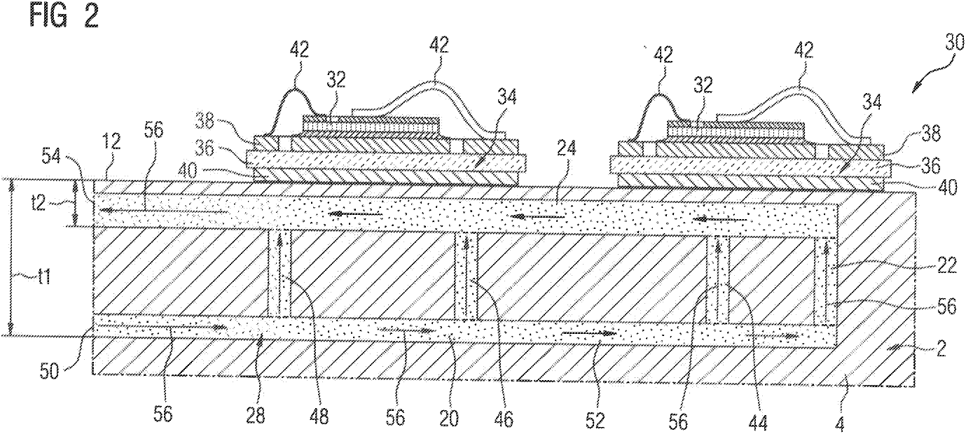

FIG. 2 shows a schematic cross-sectional view of a first embodiment of a semiconductor arrangement 30 that includes semiconductor elements 32. The semiconductor elements 32 are designed, for example, as vertical power transistors, in particular as insulated gate bipolar transistors (IGBT) and are each connected in a material-bonded manner to a substrate 34. For example, the IGBTs are connected on the collector side to the respective substrate 34. The material-bonded connection can be i.a. a solder connection and/or a sinter connection but also an adhesive connection, for example using an electrically and thermally conductive adhesive. The substrates 34 have in each case a dielectric material layer 36, a first metal coating 38, which is arranged on a side facing the semiconductor element 32, and a second metal coating 40 that is arranged on a side remote from the semiconductor element 32. The dielectric material layer 36 can include, i.a., a ceramic material, for example aluminum nitride or aluminum oxide, or an organic material, for example a polyamide or epoxy resin. Moreover, the IGBTs are connected to the first metal coating 38 of the respective substrate 34 on the gate- and emitter-side via bonded connections 42, in particular via bonding wires or bonding ribbons. The second metal coating 40 of the respective substrate 34 is connected to the surface 12 of the cooling apparatus 2 in a material-bonded manner, for example via a solder connection. Alternatively, the second metal coating 40 of the respective substrate 34 can be connected using heat conductive paste to the surface 12 of the cooling apparatus 2. Consequently, the IGBTs are connected to the cooling apparatus 2 in an electrically insulating and thermally conductive manner.

The cooling apparatus 2 has a first cooling channel 20 and a second cooling channel 24, which are connected by connecting channels 22, 44, 46, 48. The cooling channels 20, 24 and the connecting channels 22, 44, 46, 48 are produced by using FSC methods, as described in FIG. 1. Moreover, the first cooling channel 20 has a first fluid connection 50 which is provided by way of example for externally supplying a heat transfer fluid 52, while the second cooling channel 24 has a second fluid connection 54 which is provided by way of example for externally discharging the heat transfer fluid 52. A heat transfer fluid 52 of this type can be electrically conductive or electrically non-conductive. I.a., air, in particular deionized, water, a water-glycol mixture, dielectric fluids and/or oils are possibilities. Consequently, the first cooling channel 20, the second cooling channel 24 and the connecting channels 22, 44, 46, 48, form an open cooling channel structure 28. Heat transfer takes place via a flow 56 of the heat transfer medium 24 through the cooling channels 20, 24 and through the connecting channels 22, 44, 46, 48. By skillfully arranging the cooling channel structure 28, it is possible to locally reduce the heat transfer coefficients by employing the effect of impingement cooling, in addition to guiding the medium in an optimized manner. The further embodiment of the cooling apparatus 2 in FIG. 2 corresponds to that in FIG. 1.

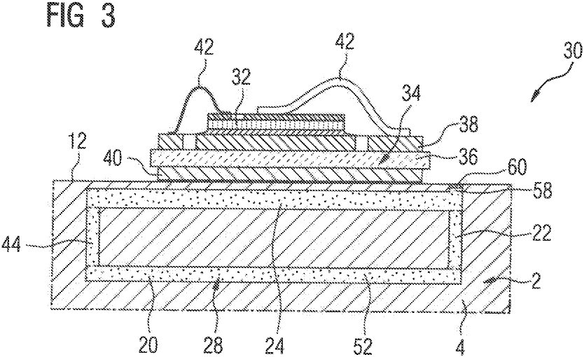

FIG. 3 shows a schematic cross-sectional view of a second embodiment of a semiconductor arrangement 30, wherein a first cooling channel 20, a second cooling channel 24 and connecting channels 22, 44 form a closed cooling channel structure 28. At least one of the cooling channels 20, 24 extends in a meandering manner, wherein the cooling channel structure 28 having the heat transfer fluid 52 is configured for a two-phase cooling. By way of example, a pulsating heat pipe is designed in FIG. 3.

A supply channel 58 which is produced by using the second FSC method and which extends from the second cooling channel 24 to the surface 12 of the metal body 4 is used to fill the cooling channel structure 28 with the heat transfer fluid 52. In addition, the supply channel 58 is closed fluid-tight by a removable closure element 60, for example by a sealing plug. The further embodiment of the semiconductor arrangement 30 in FIG. 3 corresponds to that in FIG. 2.

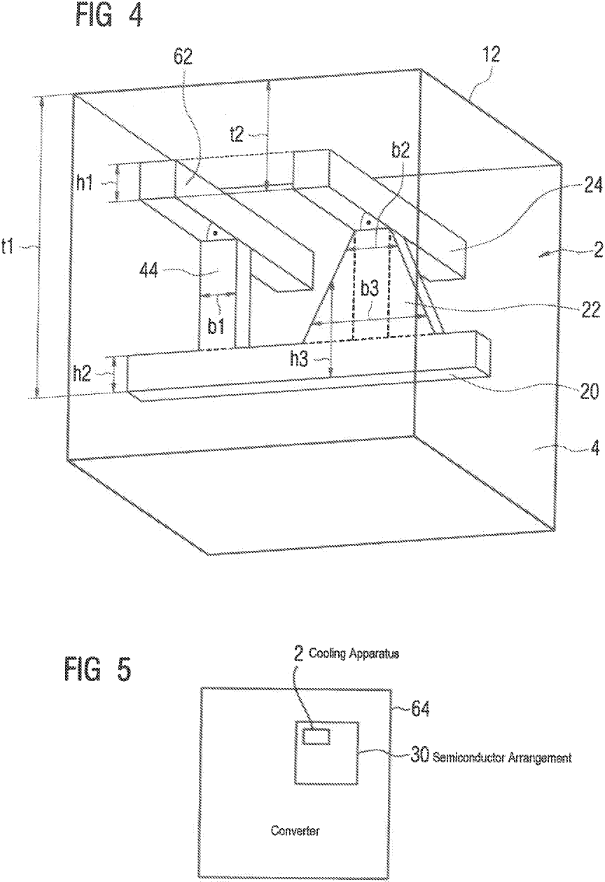

FIG. 4 shows a schematic three-dimensional illustration of a cooling apparatus 2 which has a first cooling channel 20 that is arranged at a first depth t1 in the metal body 4 and is produced by using a first FSC method. Moreover, the cooling apparatus 2 includes a first connecting channel 22 and a second connecting channel 44 which are also produced by using the first FSC method and extend from the first cooling channel 20 to the planar surface 12 of the metal body 4. In addition, the cooling apparatus 2 includes a second cooling channel 24 and a third cooling channel 62 that extends parallel to the second cooling channel 24. Furthermore, the second cooling channel 24 is connected to the first cooling channel 20 via the first connecting channel 22, while the third cooling channel 62 is connected to the first cooling channel 20 via the second connecting channel 44.

The FSC method works with a balanced process in that exactly as much material is moved out as is required for the desired channel cross-section. The material that is not removed collects in the region of the shoulder 10 (cf. FIG. 1) and generates the closed channel. The rate at which material is moved depends i.a. on the tool geometry, the rotational speed, the traverse speed and the plasticization of the material. When the cooling channels 20, 24, 62 are produced using the respective FSC method, the channel height h1, h2, h3 can consequently be modified by varying a rotational speed of the respective tool 6 and/or by varying a traversing speed of the respective tool 6. If more material is moved out at one site, a channel at this site is taller. The process parameters can also be modified gradually, whereby a contour is formed in the channel ceiling.

While the channel height h1 of the second cooling channel 24 and the third cooling channel 62 is constant, which can be achieved by a constant rotational speed and a constant traversing speed of the tool 6, the first cooling channel 20 has in the region of the first connecting channel 22 a channel height h2, h3 that decreases or falls, in particular in a linear manner. An increasing channel height h2, h3 can be achieved, for example, by a gradual drop in the traversing speed and/or an increase in the rotational speed of the tool 6. A reducing channel height h2, h3 can be achieved, for example, by gradually increasing the traversing speed and/or reducing the rotational speed of the tool 6. The channel height h2, h3 of the first connecting channel 20 in the region of the connecting channel 22, 44 influences the channel width b1, b2, b3 of the respective connecting channels 22, 24. A channel width b2, b3 of the first connecting channel 22 is modified by gradually decreasing and/or increase in the traversing speed and/or the rotational speed of the tool 6. In this manner, is such a tapering connecting channel 22, wherein the channel width b2, b3 reduces toward the surface 12, in particular in a monotone manner, moreover in particular in a linear manner. By modifying the channel height h1, h2, h3 of a cooling channel 20, 24, 62 or channel width b1, b2, b3 of a connecting channel 22, 44, heat transfer can be improved, for example in the region of hotspots. The further embodiment of the cooling apparatus 2 in FIG. 4 corresponds to that in FIG. 1.

FIG. 5 shows a schematic view of a converter 64 that includes by way of example a semiconductor arrangement 30. The semiconductor arrangement 30 includes by way of example a cooling apparatus 2.

In summary, the invention relates to a method for producing an apparatus 2 for cooling a semiconductor arrangement. In order to propose a cost-effective and simple production method that enables an improved cooling of the semiconductor arrangement, the following steps are proposed: producing by using a first FSC method a first cooling channel 20 at a first depth t1 in the metal body 4, producing by using the first FSC method a first connecting channel 22 which is arranged running from the first cooling channel 20 to an, in particular planar, surface 12 of the metal body 4, producing by using a second FSC method a second cooling channel 24 at a second depth t2 in the metal body 4, wherein the second depth t2 is smaller than the first depth t1, wherein a fluidic connection is produced between the first cooling channel 20 and the second cooling channel 24 via the first connecting channel 22, wherein the cooling channels 20, 24 and the first connecting channel 22 form a cooling channel structure 28.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A method for producing an apparatus for cooling a semiconductor arrangement, the method comprising:
producing in a metal body with a first FSC (Friction Stir Channeling) method a first cooling channel at a first depth from a surface of the metal body;
producing with the first FSC method a first connecting channel extending from the first cooling channel to the surface of the metal body; and
producing with a second FSC method in the metal body a second cooling channel at a second depth from the surface of the metal body smaller than the first depth;
wherein the first connecting channel forms a fluidic connection between the first cooling channel and the second cooling channel, and
wherein the first and second cooling channels and the first connecting channel form a cooling channel structure.

2. The method of claim 1, wherein the first connecting channel extends substantially perpendicular to the first cooling channel or to the surface of the metal body.

3. The method of claim 1, wherein the first cooling channel or the second cooling channel, or both, extend substantially parallel to the surface of the metal body.

4. The method of claim 1, wherein the first cooling channel is produced with a first tool having a first welding mandrel, and the second cooling channel is produced with a second tool having a second welding mandrel, with the first welding mandrel sized longer than the second welding mandrel.

5. The method of claim 4, further comprising modifying a channel height of the first cooling channel by varying a rotational speed of the first tool or by varying a traversing speed of the first tool.

6. The method of claim 4, further comprising modifying a channel height of the second cooling channel by varying a rotational speed of the second tool or by varying a traversing speed of the second tool.

7. The method of claim 4, further comprising modifying a channel width of the first connecting channel by gradually decreasing or Increasing a rotational speed or a traversing speed of the first or second tool.

8. The method of claim 1, wherein at least one of the first and second cooling channels has a meandering shape.

9. The method of claim 1, further comprising:
producing using the second FSC method a supply channel extending from the second cooling channel to the surface of the metal body;
filling the cooling channel structure via the supply channel with a heat transfer fluid; and
closing the supply channel.

10. The method of claim 9, wherein the cooling channel structure is configured with the heat transfer fluid for two-phase cooling.

11. The method of claim 1, wherein the metal body is constructed from aluminum, copper or an alloy of aluminum and copper.

12. The method of claim 1, wherein the surface of the metal body is planar.

13. Apparatus for cooling a semiconductor arrangement, the apparatus comprising:
a metal body; and
a cooling channel structure comprising a first cooling channel extending in the metal body at a first depth from a surface of the metal body and produced by using a first FSC method, a second cooling channel extending in the metal body at a second depth from the surface and produced by using a second FSC method, and a first connecting channel extending in the metal body from the first cooling channel to the surface and produced by using the first FSC method, with the first connecting channel connecting the first cooling channel in a fluidic manner to the second cooling channel.

14. The apparatus of claim 13, wherein the first connecting channel extends substantially perpendicular to the first cooling channel or to the surface of the metal body.

15. The apparatus of claim 13, wherein at least one of the first cooling channel and the second cooling channel is arranged substantially parallel to the surface of the metal body.

16. The apparatus of claim 13, wherein the cooling channel structure comprises a heat transfer fluid and is configured for two-phase cooling.

17. The apparatus of claim 13, wherein the surface of the metal body is planar.

18. A semiconductor arrangement, comprising:
an apparatus as set forth in claim 13; and
a semiconductor element connected to the apparatus in a thermally conductive manner.

19. A converter, comprising a semiconductor arrangement as set forth in claim 18.
